(19) United States
(12) Patent Application Publication
(10) Pub. No.: US 2008/0089374 A1
(43) Pub. Date: Apr. 17, 2008

(54) Semiconductor laser

(75) Inventors: Christoph Eichler, Tegemheim (DE); Alfred Lell, Maxhutte-haidhof (DE); Christian Rumbolz, Lappersdorf (DE)

Correspondence Address: COHEN PONTANI LIEBERMAN & PAVANE LLP, Suite 1210, 551 fifth Avenue, New York, NY, 10176, US

(73) Assignee: OSRAM Opto Semiconductors GmbH, Regensburg (DE)

(21) Appl. No.: 11/906,410

(22) Filed: Oct. 1, 2007

(30) Foreign Application Priority Data
Sep. 29, 2006 (DE) 10 2006 046 297.1

(51) Int. Cl. H01S 5/22

(52) U.S. Cl. 372/45.01

(57) ABSTRACT

A semiconductor laser comprising a semiconductor layer sequence (2) comprising an active zone (3) for generating electromagnetic radiation, and an absorber zone for attenuating higher modes. The absorber zone is arranged within the semiconductor layer sequence (2) or adjoins the semiconductor layer sequence (2).

### RELATED APPLICATION

This patent application claims the priority of German patent application 10 2006 046 297.1 filed Sep. 29, 2006, the disclosure content of which is hereby incorporated by reference.

### FIELD OF THE INVENTION

The invention relates to a semiconductor laser, in particular to a single-mode semiconductor laser.

### BACKGROUND OF THE INVENTION

Lasers having good beam quality, high coherence length and small spectral width are desirable or even necessary for many applications. These properties can be obtained in particular with single-mode lasers such as, for example, DFB lasers, surface emitting semiconductor lasers (VCSEL—Vertical Cavity Surface Emitting Laser) or ridge lasers.

The patent specification U.S. Pat. No. 6,711,197 B2 describes a ridge laser having a p-type cladding layer composed of AlGaN, wherein an SiO₂ film and an Si film disposed downstream of the SiO₂ film for absorption of higher modes are arranged on the p-type cladding layer.

In the case of the laser described, the SiO₂ film must be sufficiently thin in order that higher modes can reach right into the Si film and be absorbed. The small thickness of the SiO₂ film can have a disadvantageous effect on the electrical properties; in particular, the breakdown strength can be reduced or leakage currents can occur.

### SUMMARY OF THE INVENTION

It is an object of the present invention to provide a semiconductor laser which supplies a comparatively high beam quality in conjunction with improved electrical properties.

This and other objects are attained in accordance with one aspect of the present invention directed to a semiconductor laser comprising a semiconductor layer sequence having an active zone for generating electromagnetic radiation, and an absorber zone for attenuating higher modes, wherein the absorber zone is arranged within the semiconductor layer sequence or adjoins the semiconductor layer sequence.

Higher modes of 1^{st} and 2^{nd} order occur, in particular, without an absorber zone. In an advantageous manner, the proportion of the higher modes can be significantly reduced by means of the absorber zone and the beam quality can thus be correspondingly improved. The respective measures proposed in the context of the invention for absorption of the higher modes are preferably not mode-specific, but rather are suitable for the higher modes that occur overall.

The semiconductor laser according to the invention can be produced in two embodiments: as an edge emitting semiconductor laser or a surface emitting semiconductor laser. In the case of the edge emitting semiconductor laser, the emission takes place in the extension direction of the pumped active zone and the laser radiation emerges via the lateral flanks of the active zone. In the case of the surface emitting semiconductor laser, the laser radiation emerges at right angle to the pumped active zone.

The active zone can have, for example, a pn junction, a double heterostructure, a single quantum well or particularly preferably a multiple quantum well structure (MQW). Such structures are known to the person skilled in the art and are therefore not explained in any greater detail here. Examples of MQW structures are described in the documents U.S. Pat. No. 6,849,881, U.S. Pat. No. 6,172,382, U.S. Pat. No. 5,831,277, and U.S. Pat. No. 5,684,309, the disclosure content of all of which relating to the MQW structures is hereby incorporated by reference.

In accordance with one preferred variant, the absorber zone has an absorbing material.

In accordance with a further preferred variant, the absorbing material is an oxide or nitride, in particular an ITO or an oxide or nitride of Si, Ti, Al, Ga, Nb, Zr, Ta, Hf, Zn, Mg, Rh, In. These materials are particularly suitable in the case of a semiconductor laser based on nitride compound semiconductors, as is preferred in the context of the invention.

In the present connection, “based on nitride compound semiconductors” means that at least one layer of the semiconductor layer sequence comprises a nitride compound semiconductor material, preferably AlₙGaₘIn₁₋ₙ₋ₘN, where 0≦n≦1, 0≦m≦1 and n+m≦1. In this case, said material need not necessarily have a mathematically exact composition according to the above formula. Rather, it can have one or a plurality of dopants and also additional constituents which do not substantially change the characteristic physical properties of the AlₙGaₘIn₁₋ₙ₋ₘN material. For the sake of simplicity, however, the above formula comprises only the essential constituents of the crystal lattice (Al, Ga, In, N) even though these can be replaced in part by small quantities of further substances.

Preferably, the radiation emitted by the semiconductor laser has a wavelength in the ultraviolet, blue or green spectral range.

Preferably, the absorptance of the absorber zone is set by means of the material composition. In particular, the composition of the absorbing material is non-stoichiometric. This means that there is no stoichiometry present with regard to the material composition, that is to say that a composition does not follow quantitative laws. While the composition SiO₂ can be referred to as stoichiometric, SiO_{1.6}, a composition that is preferred in the present case, is non-stoichiometric.

In an advantageous manner, in the variant mentioned, the material composition or the absorptance can also be changed subsequently, that is to say for example after the production of the semiconductor laser or first measurements of the beam quality. In particular, a greatly absorbing material such as Si can be oxidized in a specific manner and the absorptance can thereby be reduced. This has the advantage, for example, that a plurality of semiconductor lasers can be produced together and subsequently be configured correspondingly depending on the requirement (for example with a low threshold current or high secondary mode suppression).

This advantage is also afforded in a further configuration, in which the absorber zone has an absorbing doped semiconductor material. The absorptance in this case can be set by means of the doping. Since the band gap of the semiconductor material can be varied by means of the doping, it is possible to choose the band gap in such a way that higher modes are absorbed, while the fundamental mode is amplified in the semiconductor laser and finally coupled out. In the semiconductor laser according to an embodiment of the invention, the absorber zone is doped with Mg. Suitable semiconductor materials are a semiconductor material based on phosphide, arsenide or nitride, Si or Ge.

As an alternative, the semiconductor material is undoped. By way of example, the semiconductor material can be AlₙGaₘIn₁₋ₙ₋ₘP, AlₙGaₘIn₁₋ₙ₋ₘAs or AlₙGaₘIn₁₋ₙ₋ₘN, where 0≦n≦1, 0≦m≦1 and n+m≦1. In this case, the band gap and hence the absorptance in the absorber zone can likewise be set by means of the material composition of the semiconductor material, in particular by variation of the In and/or Al proportion.

In accordance with one preferred configuration, the absorber zone comprises a dielectric material. In particular, the dielectric material can be an oxide or nitride, as listed above.

In accordance with another preferred configuration, the absorber zone is electrically insulating. As a result, the absorber zone can advantageously additionally serve as passivation for preventing breakdowns or leakage currents. The absorber zone can have, for example, silicon nitride in a region facing the active zone and silicon oxide in a region remote from the active zone. In the case of silicon nitride, a non-stoichiometric material composition can be obtained in a simple manner and the absorptance can advantageously be set thereby. By contrast, silicon oxide is suitable for passivation.

In particular, the electrically insulating absorber zone can serve as a current baffle. The current injection into the semiconductor laser can thus be limited to a desired region.

In a further embodiment, absorbing inclusions are admixed with the absorber zone. The inclusions are expediently suitable for attenuating or absorbing higher modes.

The absorptance of the absorber zone can be set by means of the proportion of the inclusions. Since differences in the optical properties of the semiconductor lasers can occur on account of production, a settable absorptance is particularly advantageous.

The inclusions can be atoms, clusters or particles which comprise or consist of a metal, semiconductor material or organic material. In particular, the inclusions can comprise or consist of Ti, Pt, Si or C.

The absorber zone comprising the inclusions can contain an oxide or nitride, in particular an ITO or an oxide or nitride of Si, Ti, Al, Ga, Nb, Zr, Ta, Hf, Zn, Mg, Rh, In or a polyimide.

The absorptance can be set by means of the proportion of the inclusions.

Furthermore, the absorber zone can have a super lattice formed from a sequence of at least one layer containing an absorbing material and at least one layer containing a less absorbing material. For example, Si can be used as absorbing material and an oxide or nitride, as listed above, as less absorbing material.

Furthermore, the absorptance of the absorber zone can be set by means of diffusion of absorber material into the absorber zone or from the absorber zone. This variant makes it possible to regulate the overlapping of the absorber zone with the radiation field of the semiconductor laser. By means of a diffusion of the absorber material nearer to the active zone, the overlapping with the radiation field can be increased, whereby a greater absorption can be obtained. Conversely, by means of a diffusion of the absorber material away from the radiation field, a reduction of the overlapping with the radiation field can be effected, whereby a lower absorption takes place. In this case, there is the possibility of thermally and/or electrically supporting or controlling the diffusion.

In one particular configuration of the semiconductor laser, the absorber zone is structured. By means of the structuring, the absorption in the absorber zone can be reduced on account of the reduction of the absorbing area in comparison with a whole-area application. This is advantageous particularly in the case of a greatly absorbing material. By way of example, the absorber zone can have a point-type, strip-type or field-line-like structure. Furthermore, single or multiply repeating structures are conceivable. The absorber zone can firstly be applied over the whole area and subsequently be structured or be applied already in structured fashion. The latter is advantageous in the case of resonator mirrors, for example, because this means that damage or contamination of the resonator mirrors by subsequent structuring can be prevented. In an advantageous manner, the absorption of individual transverse and/or longitudinal modes can be set in a specific manner by structured application or by alteration of the spatial distribution of the absorber material.

In the case of an array of semiconductor lasers, in which a semiconductor laser arranged in the center typically becomes warmer during operation than a semiconductor laser arranged at the edge, the different operating conditions can be taken into account by means of differently configured absorber zones.

In accordance with one embodiment of the semiconductor laser, the absorber zone is a mask layer used for epitaxial lateral overgrowth (ELOG). The ELOG method is advantageous particularly in the case of an absorber zone arranged within the semiconductor laser sequence, since it is thereby possible to incorporate a zone into the semiconductor layer sequence which contains a material that differs from the semiconductor material used for the semiconductor layer sequence. The absorber zone serving as ELOG mask layer can be applied by sputtering or vapor deposition and structured. After the production of the absorber zone, the semiconductor layer sequence is grown further.

The configurations described below are suitable particularly in the case of an absorber zone adjoining the semiconductor layer sequence.

In a particular embodiment, the absorber zone is formed from a layer terminating the semiconductor layer sequence by means of altering the crystal structure of the semiconductor layer sequence. As a result, the absorber zone has altered absorption properties in comparison with the semiconductor layer sequence. By way of example, the crystal structure can be altered by means of plasma or temperature action. Plasma damages or absorption centers arise in this case. In the case of GaN, Ga absorption centers are formed for example by evaporation of N₂.

Furthermore, the absorber zone can be formed from a metal layer. In particular, the metal layer is applied to the semiconductor layer sequence. However, it is also conceivable to implant or indiffuse a metal as absorber material into the semiconductor layer sequence.

The metal layer can contain a metal having a low work function, for example Ti, Al or Cr. As a result, the metal layer is not suitable as an electrical contact, and no current injection or pumping of the active zone takes place in the region of the absorber zone.

In accordance with one variant of the semiconductor laser, an electrical insulation layer is arranged on a side of the absorber zone that is remote from the semiconductor layer sequence. In particular, the electrical insulation layer is provided for improving the electrical properties of the semiconductor laser independently of the absorption effect of the absorber zone adjoining the semiconductor layer sequence.

The insulation layer further preferably has a different refractive index than the absorber zone. In an advantageous manner, given a sufficiently thin absorber zone, the penetration depth of the radiation field into the electrical insulation layer can be set by way of the refractive index thereof, whereby the overlapping of the radiation field with the absorber zone and hence the absorption effect thereof can in turn be set. By way of example, the refractive index can be altered by oxidation of the material used for the absorber zone.

For different degrees of attenuation of different modes, a gradual or stepped change in the absorptance can be produced both by means of the material composition in the absorber zone and by means of suitable structuring of the absorber zone. By way of example, the structures of the absorber zone can be distributed in varying density, such that regions of a mode which lie further outward are absorbed to a greater extent.

In a further embodiment, the absorber zone has a metal contact for electrically setting the absorption. In the region of the metal contact, the absorption of the active zone is set by pumping between transparent and greatly absorbing, such that, in particular, higher modes are attenuated to a greater extent than the fundamental mode.

In principle, all the described variants are conceivable in the case of edge emitting semiconductor lasers with a ridge structure, with gain-guided structures, for example oxide-stripe lasers, in the case of laser arrays and in the case of surface emitting semiconductor lasers.

The absorber zone in the case of a ridge laser can extend in a lateral direction. The layers of the semiconductor layer sequence typically likewise extend in a lateral direction. In particular, the absorber zone and the semiconductor layer sequence are arranged essentially parallel to one another. Furthermore, the absorber zone in the case of the ridge laser is particularly preferably spaced apart from the active zone in a vertical direction.

In an advantageous manner, higher kink levels can be obtained with the semiconductor laser according to an embodiment of the invention in comparison with conventional semiconductor lasers, that is to say that higher radiation powers can be achieved without transverse mode jumps occurring.

The semiconductor laser according to the invention is suitable for numerous applications such as for data storage or for laser printing.

In the context of the invention, for example sputtering, vapor deposition, epitaxial growth or plasma coating are appropriate for producing the absorber zone.

### BRIEF DESCRIPTION OF THE DRAWINGS

FIG. 1 shows a schematic cross-sectional view of a first exemplary embodiment of a semiconductor laser according to the invention,

FIG. 2 shows a schematic cross-sectional view of a second exemplary embodiment of a semiconductor laser according to the invention,

FIG. 3 shows a schematic cross-sectional view of a third exemplary embodiment of a semiconductor laser according to the invention,

FIG. 4 shows a schematic cross-sectional view of a fourth exemplary embodiment of a semiconductor laser according to the invention,

FIGS. 5a, 5b, 5c, 5d, 5e show a schematic illustration of exemplary embodiments of structures of absorber zones according to the invention,

FIG. 6 shows a schematic cross-sectional view of a fifth exemplary embodiment of a semiconductor laser according to the invention,

FIG. 7 shows a schematic cross-sectional view of a sixth exemplary embodiment of a semiconductor laser according to the invention,

FIG. 8 shows a schematic cross-sectional view of a seventh exemplary embodiment of a semiconductor laser according to the invention,

FIGS. 9a and 9b show graphs representing the internal loss of a conventional semiconductor laser and of a semiconductor laser according to the invention as a function of the etching depth,

FIGS. 10a and 10b show graphs representing the angle-dependent intensity distribution of a conventional semiconductor laser and of a semiconductor laser according to the invention,

FIGS. 11a and 11b show two graphs representing the threshold gain characteristic of conventional ridge lasers.

### DETAILED DESCRIPTION OF THE DRAWINGS

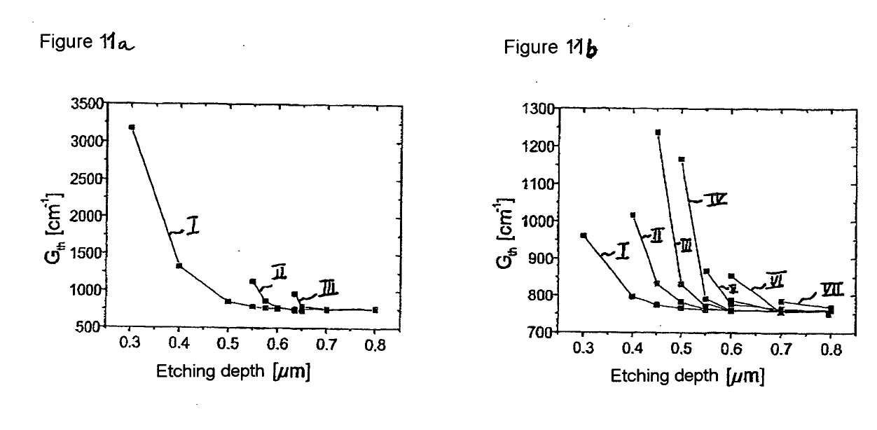

In FIGS. 11a and 11b, the threshold gain Gₜₕ is plotted against the etching depth in a respective graph for two conventional ridge lasers.

FIG. 11a relates to a ridge laser having a ridge width of 1.5 μm, while FIG. 11b relates to a ridge laser having a ridge width of 5 μm. The various curves specify the threshold gain profile for various modes (curve I: fundamental mode; curve II: 1^{st} order; curve III: 2^{nd} order; curve IV: 3^{rd} order; curve V: 4^{th} order; curve VI: 6^{th} order; curve VII: 9^{th} order).

Both graphs reveal that the threshold gain decreases as the etching depth increases. Likewise, the threshold gain decreases as the ridge width increases. What is problematic in both cases is that higher-order modes occur at increasing etching depth. As emerges from FIG. 11b, in the case of a wider ridge the higher-order modes already arise at smaller etching depths.

Possible options as to how higher modes can be attenuated despite a large etching depth or despite a wider ridge are demonstrated below.

The illustrations of the semiconductor lasers have a wavy line at the lower edge, and said line is intended to illustrate that a semiconductor layer sequence 2 is not fixed to a specific configuration on this side. Conventional configurations of a semiconductor laser are suitable on this side. In particular, the semiconductor laser can have there a cladding layer, a waveguide layer, a mirror layer, a substrate and a contact layer.

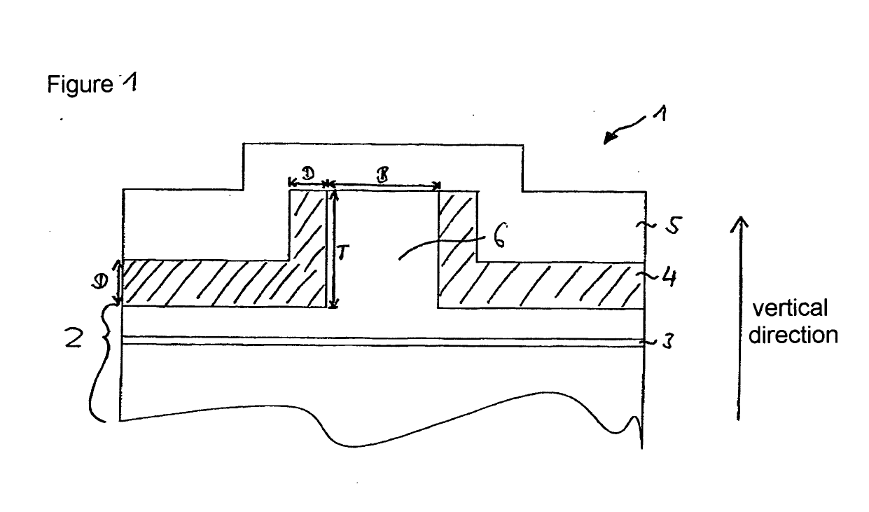

FIG. 1 illustrates a semiconductor laser 1 comprising a semiconductor layer sequence 2, the layers (not individually illustrated) of which are arranged one above another in the vertical direction indicated. The semiconductor layer sequence 2 comprises an active zone 3, which generates electromagnetic radiation during operation. Preferably, the generated radiation is emitted laterally in this exemplary embodiment, that is to say in a direction essentially perpendicular to the vertical direction. The active zone 3 is formed from a semiconductor material suitable for generating radiation having a desired wavelength. Preferably, the active zone 3 contains a nitride-based compound semiconductor material, in particular GaN, and emits radiation having a wavelength in the green/blue spectral range. The wavelength can be approximately 405 nm, for example.

In the exemplary embodiment illustrated, an absorber zone 4 adjoins the semiconductor layer sequence 2. In this case, the absorber zone 4 is sufficiently electrically nonconductive and thick enough, such that it simultaneously serves as passivation, whereby the breakdown strength is advantageously increased and leakage currents are reduced. The thickness D of the absorber zone 4 is in the region of 250 nm, for example, given an operating voltage of approximately 12 V to 15 V. Furthermore, the absorber zone 4 can contain two materials, for example silicon nitride and silicon oxide, wherein the materials can be contained in particular in layers arranged one above another.

A contact layer 5 for making electrical contact with the semiconductor layer sequence 2 is disposed downstream of the absorber zone 4 in the vertical direction.

The semiconductor laser 1 can be, as illustrated, a ridge laser having a ridge 6. The semiconductor laser 1 has an etching depth T and a ridge width B. The absorber zone 4 covers the semiconductor layer sequence 2, preferably including the sidewalls of the ridge 6. Only a strip-type region for current injection is not covered by the absorber zone 4. In this region, the contact layer 5 directly adjoins the semiconductor layer sequence 2.

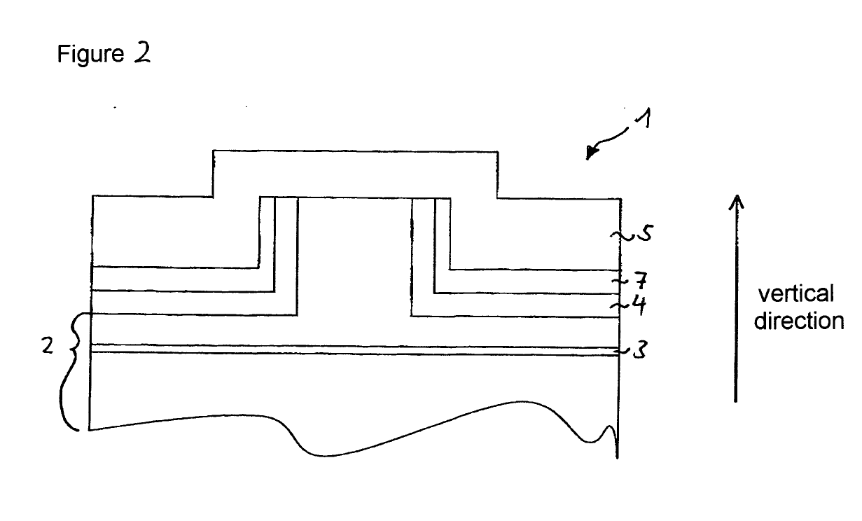

FIG. 2 illustrates a semiconductor laser 1 having a thinner absorber zone 4 in comparison with the semiconductor laser 1 in accordance with FIG. 1. In order nevertheless to largely avoid a current flow through the absorber zone 4, an insulation layer 7, which is electrically nonconductive, in particular, is disposed downstream of the absorber zone 4 on a side remote from the active zone 3. In the case of this variant, the electrical properties can advantageously be influenced independently of the optical properties. However, the optical properties can also be influenced by means of the insulation layer 7, for example by virtue of the penetration depth of the radiation field into the insulation layer 7 being defined by way of the refractive index of a material used for the insulation layer 7. The overlapping of the radiation field with the absorber zone 4 and hence the absorption effect can be defined thereby.

By way of example, in this exemplary embodiment, silicon can be used for the absorber zone 4, while silicon oxide is used for the insulation layer 7. Besides the electrical conductivity, the refractive index can be influenced by means of the oxygen proportion.

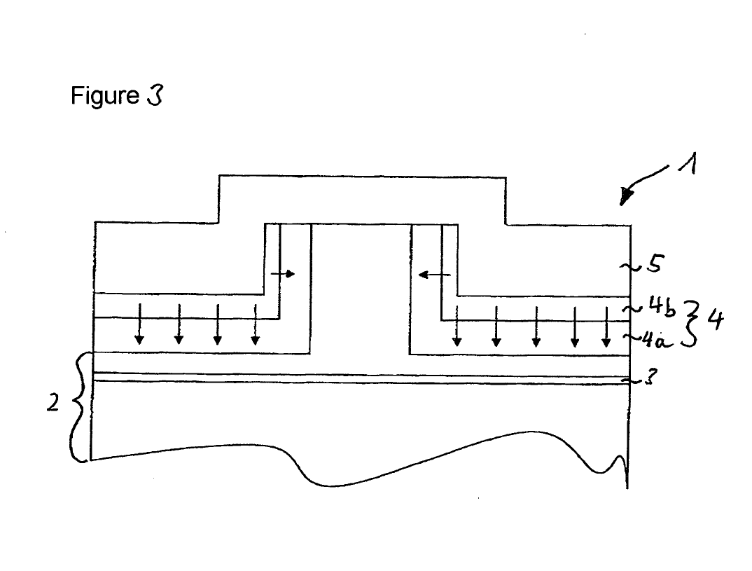

FIG. 3 illustrates a semiconductor laser 1, the absorptance of which in the region 4a of the absorber zone 4 can also be set subsequently, that is to say after the production of the semiconductor laser 1 and/or first measurements of the beam quality. The setting is effected by means of diffusion of an absorber material.

If the absorptance in the region 4a is intended to be increased, it is possible to dispose downstream of the region 4a a region 4b containing an absorber material that diffuses into the region 4a in the arrow direction. As a result of this, the absorber material moves nearer to the active zone 3, whereby the overlapping with the radiation field is increased and a greater absorption takes place. Conversely, the absorptance in the region 4a can be decreased by virtue of absorber material diffusing from said region into the region 4b. As a result of this, the absorber material is further away from the active zone 3, whereby the overlapping with the radiation field is reduced and a reduced absorption takes place.

In particular, the absorber material contains inclusions. The inclusions can be atoms, clusters or particles comprising or consisting of a metal, semiconductor material or organic material. In particular, the inclusions can comprise or consist of Ti, Pt, Si or C.

The diffusion can be assisted thermally and/or electrically.

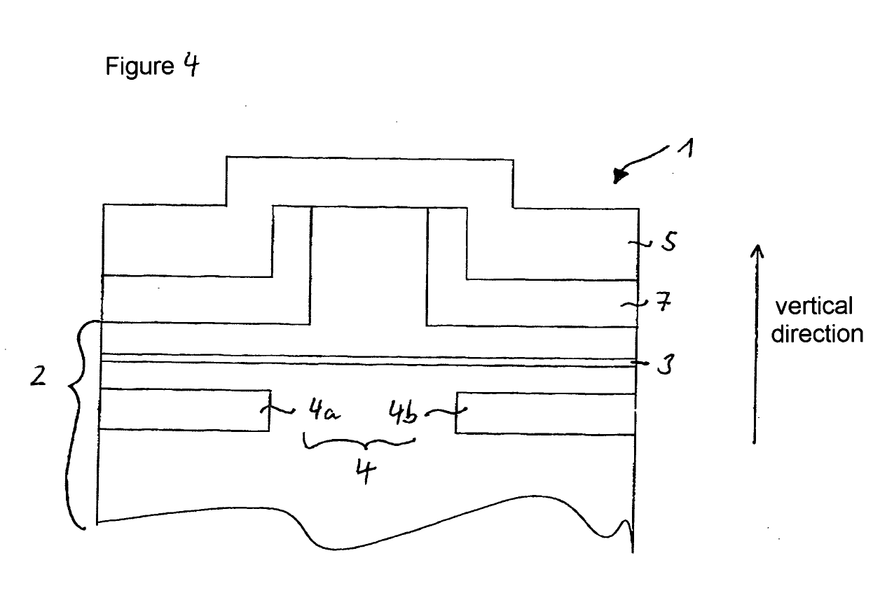

In the case of the semiconductor laser 1 illustrated in FIG. 4, the absorber zone 4 composed of the region 4a and the region 4b is arranged within the semiconductor layer sequence 2. The absorber zone 4 can be arranged above, below or alongside the active zone 3 in the vertical direction. By way of example, the absorber zone 4 can be incorporated into the semiconductor layer sequence 2 as an absorbing mask layer, in particular as an ELOG mask layer, the absorber zone 4 being epitaxially laterally overgrown. An absorber zone 4 which is arranged as in FIG. 4 and which is furthermore electrically nonconductive can simultaneously serve as a current baffle, whereby the current flow is advantageously limited to a central region of the semiconductor layer sequence 2, said central region being arranged between the absorbing regions 4a, 4b. Furthermore, the optical confinement can be improved by means of a suitable refractive index jump between the material of the absorber zone 4 and the semiconductor material of the surrounding semiconductor layer sequence 2.

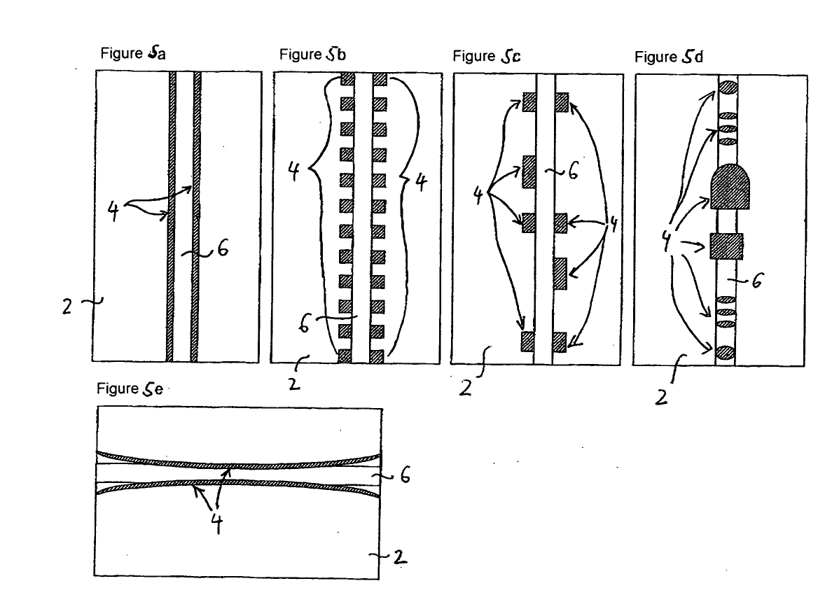

FIGS. 5a to 5e illustrate differently structured absorber zones 4. As shown in FIG. 5d, the structured absorber zone 4 can be arranged directly on the ridge 6 or the laser resonator. In addition or as an alternative, as illustrated in FIGS. 5a, 5b, 5c and 5e, the absorber zone 4 can be arranged alongside the ridge 6 or the laser resonator. By means of the structuring, it is possible advantageously to attenuate the absorption effect in the case of a greatly absorbing material.

The absorber zone 4 illustrated in FIG. 5a extends on both sides along the ridge 6 and is formed in strip-type fashion.

The absorber zone 4 illustrated in FIG. 5b also extends on both sides along the ridge 6 and is structured into rectangles of identical size which are spaced apart regularly from one another in the longitudinal direction.

The absorber zone 4 illustrated in FIG. 5c likewise extends on both sides along the ridge 6 and is structured into rectangles of different sizes which are spaced apart irregularly from one another in the longitudinal direction.

The absorber zone 4 shown in FIG. 5d is structured into different geometrical forms, in particular into elliptical, rectangular and semicircular forms.

The absorber zone 4 illustrated in FIG. 5e extends on both sides along the ridge 6 and is formed in strip-type fashion. In this case, the strips are slightly curved at the ends.

FIGS. 5a to 5b show structures for different absorbing materials. The absorption coefficient increases from the embodiment of FIG. 5a to the embodiment of FIG. 5b. As the absorption coefficient increases, the area which is covered by the absorber zone can decrease.

FIGS. 5c and 5d show irregularly structured absorber zones. This is because the ridge 6 also has irregularities as a consequence of the production process and, therefore, also the radiation field also has irregularities. So in different areas, there must be a difference in the strength of absorption.

FIG. 5e shows curved absorber lines. The absorber zones are curved at the edge of the laser where the facets are. This results in a reduced overlap between the radiation field and the absorber zone at the facets so that light can be coupled out in a better way.

In practice, the radiation field of the laser without absorber can be measured to determine where it differs from a Gaussian shape. Then, simulations can be done to find out the best position and spacing for the absorber zone by using the shapes disclosed herein in order to achieve the Gaussian shape.

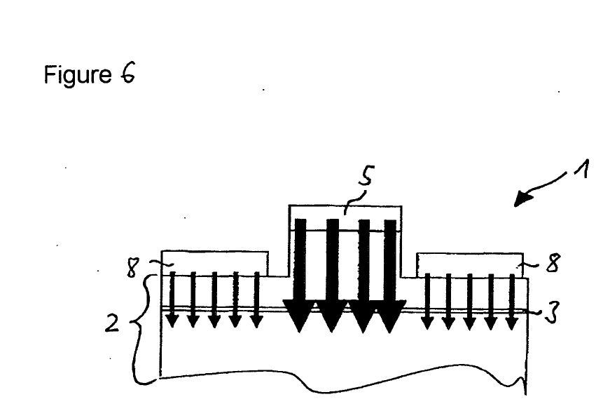

In the case of the semiconductor laser 1 illustrated in FIG. 6, the absorption is set electrically. On the semiconductor layer sequence 2, metal contacts 8 are provided in addition to the contact layer 5, by means of which metal contacts current is injected into the semiconductor laser 1. In the region of the metal contacts 8, the active zone 3 is set by pumping between transparent and greatly absorbing in such a way that, in particular, higher modes experience a greater absorption than the fundamental mode. In this case, the metal contacts 8 are energized independently of the contact layer 5. Consequently, it is possible to set the absorption in the regions of the metal contacts 8 independently of the lasing taking place in the region of the contact layer 5.

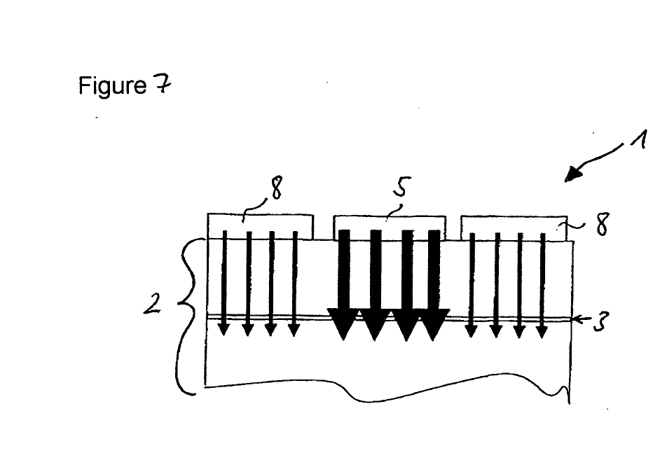

The variant of a semiconductor laser 1 which is illustrated in FIG. 7 does not differ with regard to the functional principle from the exemplary embodiment of a semiconductor laser 1 which is shown in FIG. 6. However, this semiconductor laser 1 has a lasing region that is more extensive than in the case of the exemplary embodiment illustrated in FIG. 6. In this case, it is possible to dispense with removal of the semiconductor layer sequence 2 in the region of the metal contacts 8.

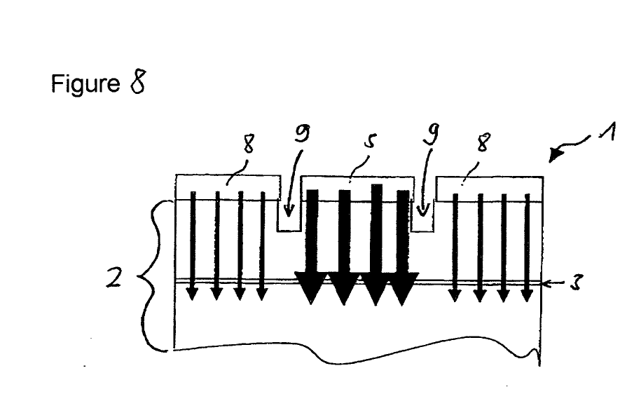

The semiconductor laser 1 illustrated in FIG. 8 additionally has isolating trenches 9 between the metal contacts 8 and the contact layer 5. This leads to a better electrical isolation of the contacts, such that current injection into the semiconductor layer sequence 2 principally takes place in the region below the contact layer 5. Furthermore, it is thereby possible to achieve better wave-guiding in the semiconductor laser 1.

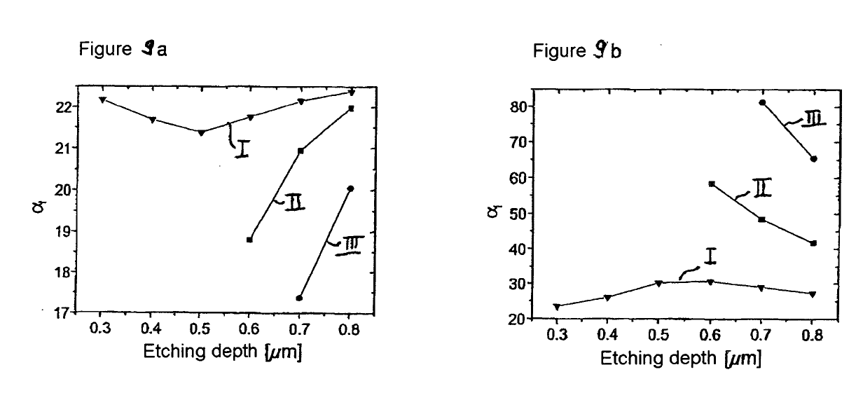

FIGS. 9a and 9b illustrate simulations of the internal loss αᵢ as a function of the etching depth for a conventional ridge laser (FIG. 9a) and a ridge laser according to the invention (FIG. 9b). The abscissa specifies the etching depth, and the ordinate specifies the internal loss αᵢ. While the conventional ridge laser has no absorber material, the ridge laser according to the invention contains TiO as absorber material, said TiO being arranged at the ridge. The ridge width is 1.5 μm in both ridge lasers.

The curves I, II and III represent the simulation results for the fundamental mode, the 1^{st}-order mode and the 2^{nd}-order mode.

As can be ascertained in a comparison of the curves, the internal loss αᵢ for higher modes is significantly higher using an absorber material than without absorber material. In an advantageous manner, it is thereby possible to effect laser operation in the fundamental mode in conjunction with low threshold gains and comparatively high optical output powers.

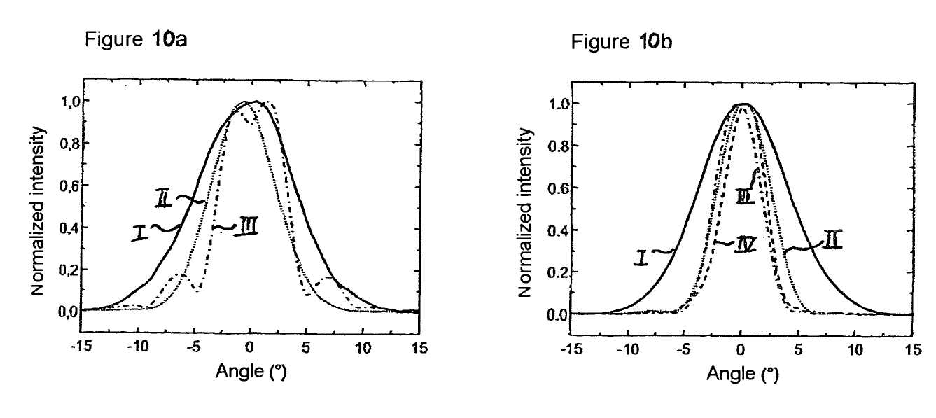

FIGS. 10a and 10b illustrate measurement results of the angle-dependent intensity distribution which were obtained with different ridge lasers. A conventional ridge laser without absorber material yields the measurements results illustrated in FIG. 10a, while a ridge laser according to the invention with absorber material, which is TiO in this case, yields the measurement results illustrated in FIG. 10b.

The angle-dependent intensity distributions are results of measurements in the vertical far field. The different curves are to be assigned to ridge lasers having different ridge widths: curve I to a ridge laser having a ridge width of 2.5 μm; curve II to a ridge laser having a ridge width of 5 μm; curve III to a ridge laser having a ridge width of 8 μm; curve IV to a ridge laser having a ridge width of 10 μm. As emerges from FIG. 10a, the intensity distribution of a ridge laser without absorber having a ridge width of 8 μm no longer corresponds to a Gaussian form. By contrast, the curves III and IV illustrated in FIG. 10b for a ridge laser according to an embodiment of the invention having identical ridge widths have a Gaussian form.

Consequently, the beam form in the vertical far field is significantly improved by the use of the absorber material. Furthermore, the use of the absorber material permits even ridge lasers having a wider ridge to be able to be operated in the fundamental mode. This has the advantage, on the one hand, that a structuring of the laser strips is significantly simplified and, on the other hand, that the operating voltage is reduced, since the contact and series resistances in the ridge laser have an inverse relationship with respect to the ridge width and the threshold current densities are lower in the case of larger ridge widths than in the case of smaller ridge widths. Furthermore, a larger ridge width can lead to higher output powers since the power density at the facet is lower and the critical power density leading to the destruction of the facet (COMD=Catastrophic Optical Mirror Damage) is thus higher.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or embodiments.

We claim:

1. A semiconductor laser comprising:
a semiconductor layer sequence comprising an active zone for generating electromagnetic radiation; and
an absorber zone for attenuating higher modes, wherein the absorber zone is arranged within the semiconductor layer sequence or adjoins the semiconductor layer sequence.

2. The semiconductor laser as claimed in claim 1, wherein the absorber zone has an absorbing material.

3. The semiconductor laser as claimed in claim 1, wherein the absorptance of the absorber zone is set by means of the material composition.

4. The semiconductor laser as claimed in claim 2, wherein the absorbing material is an oxide or nitride, in particular an ITO or an oxide or nitride of Si, Ti, Al, Ga, Nb, Zr, Ta, Hf, Zn, Mg, Rh, In.

5. The semiconductor laser as claimed in claim 2, wherein the material composition of the absorbing material is non-stoichiometric.

6. The semiconductor laser as claimed in claim 2, wherein the absorber zone comprises a dielectric material.

7. The semiconductor laser as claimed in claim 1, wherein the absorber zone is electrically insulating.

8. The semiconductor laser as claimed in claim 7, wherein the absorber zone serves as current baffle.

9. The semiconductor laser as claimed in claim 1, wherein the absorber zone contains an absorbing semiconductor material.

10. The semiconductor laser as claimed in claim 9, wherein the semiconductor material comprises AlₙGaₘIn₁₋ₙ₋ₘP, AlₙGaₘIn₁₋ₙ₋ₘAs or AlₙGaₘIn₁₋ₙ₋ₘN, wherein 0≦n≦1, 0≦m≦1 and n+m≦1.

11. The semiconductor laser as claimed in claim 9, wherein the semiconductor material is Si or Ge.

12. The semiconductor laser as claimed in claim 9, wherein the absorbing semiconductor material is doped.

13. The semiconductor laser as claimed in claim 12, wherein the absorptance of the absorber zone is set by means of the doping.

14. The semiconductor laser as claimed in claim 12, wherein the doped semiconductor material is doped with Mg.

15. The semiconductor laser as claimed in claim 1, wherein absorbing inclusions are admixed with the absorber zone.

16. The semiconductor laser as claimed in claim 15, wherein the absorptance of the absorber zone is set by means of the proportion of the inclusions.

17. The semiconductor laser as claimed in claim 15, wherein the inclusions are atoms, clusters or particles which comprise or consist of a metal, semiconductor material or organic material.

18. The semiconductor laser as claimed in claim 17, wherein the inclusions comprise or consist of Ti, Pt, Si or C.

19. The semiconductor laser as claimed in claim 15, wherein the absorber zone contains an oxide or nitride, in particular an ITO or an oxide or nitride of Si, Ti, Al, Ga, Nb, Zr, Ta, Hf, Zn, Mg, Rh, In or a polyimide.

20. The semiconductor laser as claimed in claim 1, wherein the absorber zone comprises a super lattice formed from a sequence of at least one layer containing an absorbing material and at least one layer containing a less absorbing material.

21. The semiconductor laser as claimed in claim 1, wherein the absorptance of the absorber zone is set by an absorber material being taken up into the absorber zone or an absorber material being emitted from the absorber zone by means of diffusion.

22. The semiconductor laser as claimed in claim 1, wherein the absorber zone is structured.

23. The semiconductor laser as claimed in claim 22, wherein the absorber zone has a point-type, strip-type or field-line-like structure.

24. The semiconductor laser as claimed in claim 1, wherein the absorber zone is arranged within the semiconductor layer sequence.

25. The semiconductor laser as claimed in claim 24, wherein the absorber zone is epitaxially overgrown.

26. The semiconductor laser as claimed in claim 1, wherein the absorber zone adjoins the semiconductor layer sequence.

27. The semiconductor laser as claimed in claim 26, wherein the absorber zone is formed from a layer terminating the semiconductor layer sequence by means of altering the crystal structure of the semiconductor layer sequence.

28. The semiconductor laser as claimed in claim 27, wherein the crystal structure is altered by means of plasma or temperature action.

29. The semiconductor laser as claimed in claim 26, wherein the absorber zone is formed from a metal layer.

30. The semiconductor laser as claimed in claim 29, wherein the metal layer contains a metal, in particular Ti or Cr, having a low work function.

31. The semiconductor laser as claimed in claim 26, wherein an electrical insulation layer is arranged on a side of the absorber zone that is remote from the semiconductor layer sequence.

32. The semiconductor laser as claimed in claim 31, wherein the insulation layer has a different refractive index than the absorber zone.

33. The semiconductor laser as claimed in claim 26, wherein the absorber zone has a metal contact for electrically setting the absorption.

34. The semiconductor laser as claimed in claim 1, which is a ridge laser.

35. The semiconductor laser as claimed in claim 34, wherein the absorber zone extends in a lateral direction.

36. The semiconductor laser as claimed in claim 34, wherein the absorber zone is spaced apart from the active zone in a vertical direction.

37. The semiconductor laser as claimed in claim 1, wherein the absorber zone is produced by means of sputtering, vapor deposition, epitaxial growth or plasma coating.
